(19) United States
(12) Patent Application Publication
(10) Pub. No.: US 2012/0128894 A1
(43) Pub. Date: May 24, 2012

(54) Crucible for Electron Gun Evaporation

(76) Inventors: Zhao Zhigang, Zhenjiang (CN); Liu Feng, Zhenjiang (CN)

(21) Appl. No.: 13/303,143

(22) Filed: Nov. 23, 2011

(30) Foreign Application Priority Data
Nov. 22, 2010 (CN) ZL 2010 2 0617898

(51) Int. Cl. C23C 14/30; B05D 3/06

(52) U.S. Cl. 427/566; 118/726

(57) ABSTRACT

A lower crucible component 3 comprises a lower planer surface 5 sometimes supporting an upper crucible component 1, the lower planner surface 5 having an inside section 9, outer vertical wall 11, upper crown 12, inner vertical wall 13 and upper planer surface 14 sometimes used to hold material for vaporization and attachment to ophthalmic lens such as eyeglasses. An electron gun is used to focus electrons to both the lower crucible 3 and the upper crucible component so as to evenly vaporize material held at a center section of the crucible assembly.

### RELATED PATENT APPLICATION AND INCORPORATION BY REFERENCE

This is a utility application based upon China patent application Ser. No. ZL 2010 2 0617898.4 filed on flied on Nov. 22, 2010. This related application is incorporated herein by reference and made a part of this application. If any conflict arises between the disclosure of the invention in this utility application and that in the related application, the disclosure in this utility application shall govern. Moreover, the inventor(s) incorporate herein by reference any and all patents, patent applications, and other documents hard copy or electronic, cited or referred to in this application.

### BACKGROUND OF THE INVENTION

(1) Field of the Invention

The invention generally relates to means and methods of evaporation of material to be deposited upon a surface. More particularly, the invention relates to a crucible system using an electron gun to evaporate material for coating of an optical lens.

(2) Description of the Related Art

Expensive and complicated means and methods of evaporating material for coating of optical lenses and other materials are known in the related art. For example, U.S. Pat. No. 3,274,417 issued on Sep. 20, 1966 to Haefer et al discloses an electronic evaporator for vacuum coating technology. Haefer eschewed crucible systems based on a concern that undesirable chemical reactions would occur. Haefer discloses a non-crucible system relying upon a complicated system of high vapor pressure.

U.S. Pat. No. 3,777,704 issued on Dec. 11, 1973 to Van Poucke discloses a crucible under a vacuum wherein material is vaporized by a strongly focused moving electron beam. Van Poucke requires mechanical complexity in the form of a moving electron beam and a vacuum system. Moreover, Van Pouchke contemplates the coating of an elongated or oblong substratum such as a strip or wire, a limitation prohibiting the coating of a lens.

U.S. Pat. No. 6,481,369 issued on Nov. 19, 2002 to Takahashi et al discloses means and methods of applying thin films on plastic or glass eyeglasses by use of a vaporization chamber and an electron gun. Unfortunately, the Takahashi system requires the use of a halogen heater and illumination light as well as reflection light.

U.S. Patent Application Publication 2008/0002260 published on Jan. 3, 2008 and invented by Arrouy et al discloses means and methods of applying multi-layer anti-reflection coatings upon a lens by use of exceptionally complex calculations and ratios related to thicknesses of low refractive index layers, high refractive index layers, anti-reflective coatings and accounting for layers absent of niobium pentoxide and levels of luminous reflection factors. Such variables present serious challenges to the efficient coating of lenses. Thus, there is room in the art for more efficient means of coating ophthalmic lens such as eyeglasses.

### BRIEF SUMMARY OF THE INVENTION

The present invention overcomes shortfalls in the related art by presenting an unobvious and unique combination, configuration and use of a crucible components having an inner gap area and other features and the use of an electron gun sending electrons to two the lower crucible component and the upper crucible component such that lens coating material within the crucible assembly vaporizes evenly and efficiently.

The crucible assembly is conductively heated via a graphite base and a steel upper component to vaporize lens coating material at a lower than expected temperature and thus enhance the performance of the applied lens coating material.

### BRIEF DESCRIPTION OF THE DRAWINGS

FIG. 1 depicts a sectional view of one embodiment of the invention

FIG. 2 depicts one embodiment of the invention with vectors showing the application of an electron gun

FIG. 3 depicts one embodiment of the invention without the lens coating material

FIG. 4 depicts an exploded view of certain sections of the crucible assembly

### REFERENCE NUMERALS IN THE DRAWINGS

1 an upper component of the crucible assembly
2 lens coating material, sometime vaporized within the crucible assembly
3 a lower component of the crucible assembly
4 vectors or points of contact by an electron gun to the upper and lower components of the crucible assembly
5 an upper planer support area of the lower component 3 of the crucible assembly
6 an outer surface of a vertical wall 7 of the upper component 1 of the crucible assembly
7 a vertical wall of the upper component 1 of the crucible assembly
8 an inner surface of a 7 a vertical wall of the upper component 1 of the crucible assembly
9 an inner surface area of the upper planer support area 5 of the lower component 3 of the crucible assembly
10 a gap area defined by 8, 9 and 11
11 a first vertical wall of the lower component 3 of the crucible assembly
12 a crown horizontal surface located between a first vertical wall 11 and second vertical wall 13
13 a second vertical wall of the lower component 3 of the crucible assembly
14 a raised horizontal planer surface of the lower component 3 of the crucible assembly
15 a void area defined by 13 and 14
16 an outer base area of the lower component 3 of the crucible assembly
17 an inner base area of the lower component 3 of the crucible assembly
These and other aspects of the present invention will become apparent upon reading the following detailed description in conjunction with the associated drawings.

### DETAILED DESCRIPTION OF EMBODIMENTS OF THE INVENTION

The following detailed description is directed to certain specific embodiments of the invention. However, the invention can be embodied in a multitude of different ways as defined and covered by the claims and their equivalents. In this description, reference is made to the drawings wherein like parts are designated with like numerals throughout.

Unless otherwise noted in this specification or in the claims, all of the terms used in the specification and the claims will have the meanings normally ascribed to these terms by workers in the art.

Unless the context clearly requires otherwise, throughout the description and the claims, the words “comprise,” “comprising” and the like are to be construed in an inclusive sense as opposed to an exclusive or exhaustive sense; that is to say, in a sense of “including, but not limited to.” Words using the singular or plural number also include the plural or singular number, respectively. Additionally, the words “herein,” “above,” “below,” and words of similar import, when used in this application, shall refer to this application as a whole and not to any particular portions of this application.

The above detailed description of embodiments of the invention is not intended to be exhaustive or to limit the invention to the precise form disclosed above.

While specific embodiments of, and examples for, the invention are described above for illustrative purposes, various equivalent modifications are possible within the scope of the invention, as those skilled in the relevant art will recognize. For example, while steps are presented in a given order, alternative embodiments may perform routines having steps in a different order. The teachings of the invention provided herein can be applied to other systems, not only the systems described herein. The various embodiments described herein can be combined to provide further embodiments. These and other changes can be made to the invention in light of the detailed description.

All the above references and U.S. patents and applications are incorporated herein by reference. Aspects of the invention can be modified, if necessary, to employ the systems, functions and concepts of the various patents and applications described above to provide yet further embodiments of the invention.

These and other changes can be made to the invention in light of the above detailed description. In general, the terms used in the following claims, should not be construed to limit the invention to the specific embodiments disclosed in the specification, unless the above detailed description explicitly defines such terms.

Accordingly, the actual scope of the invention encompasses the disclosed embodiments and all equivalent ways of practicing or implementing the invention under the claims.

While certain aspects of the invention are presented below in certain claim forms, the inventors contemplate the various aspects of the invention in any number of claim forms.

In general, embodiments of the disclosed systems and methods use a dual beam 4 of electrons to heat a crucible assembly, the crucible assembly comprising a lower component 3 and an upper component 1. A gap area 10 in combination with a 14 a raised horizontal planer surface 14 of the lower component 3 of the crucible assembly generates unexpected favorable results in vaporizing coating material 2 at lower temperatures. Embodiments of the invention are used with and without a vacuum of pressure inside the crucible assembly.

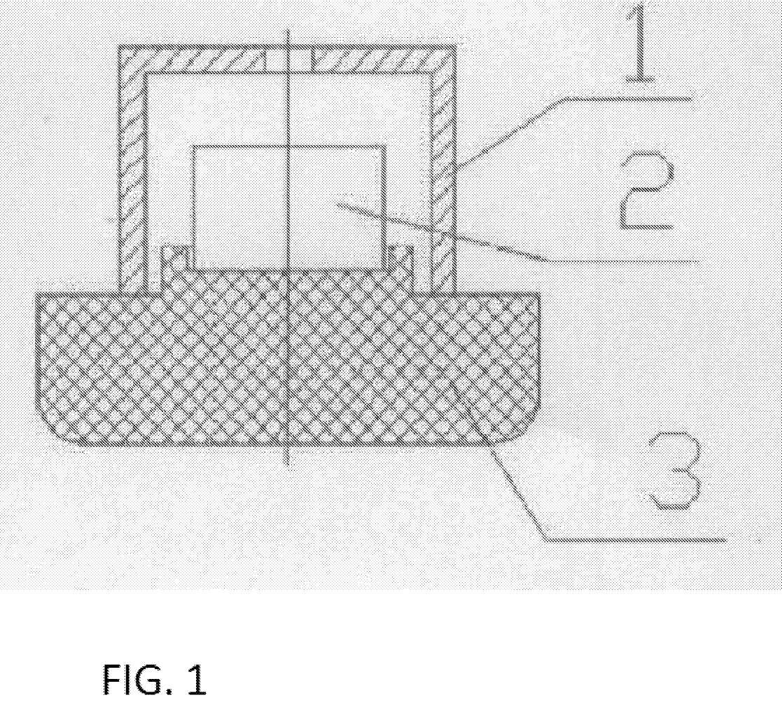

Referring to FIG. 1, an upper component 1 of the crucible assembly sits upon a lower component of the crucible assembly. A lens coating material 2 sits within the crucible assembly.

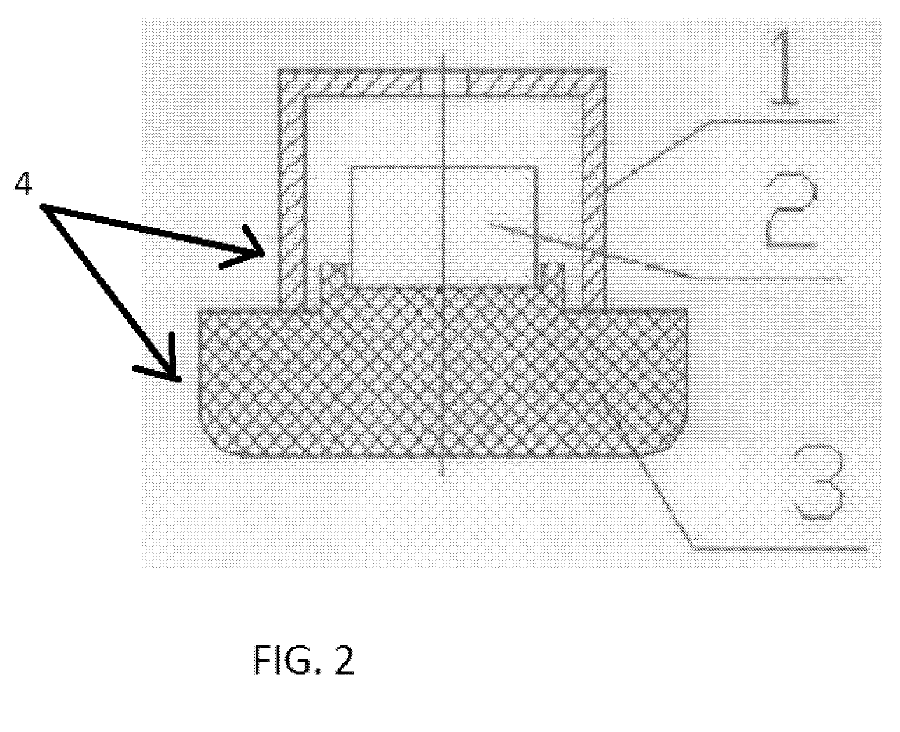

Referring to FIG. 2 electron beam vectors 4 reach both the lower and upper components of the crucible assembly.

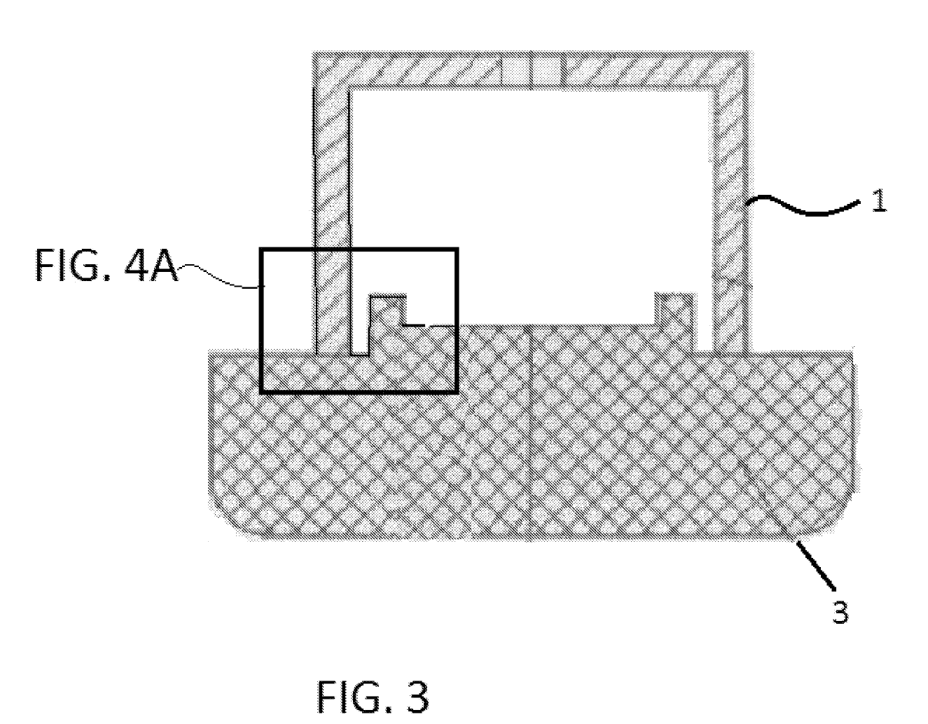

FIG. 3 shows a crucible assembly without the lens material to be vaporized.

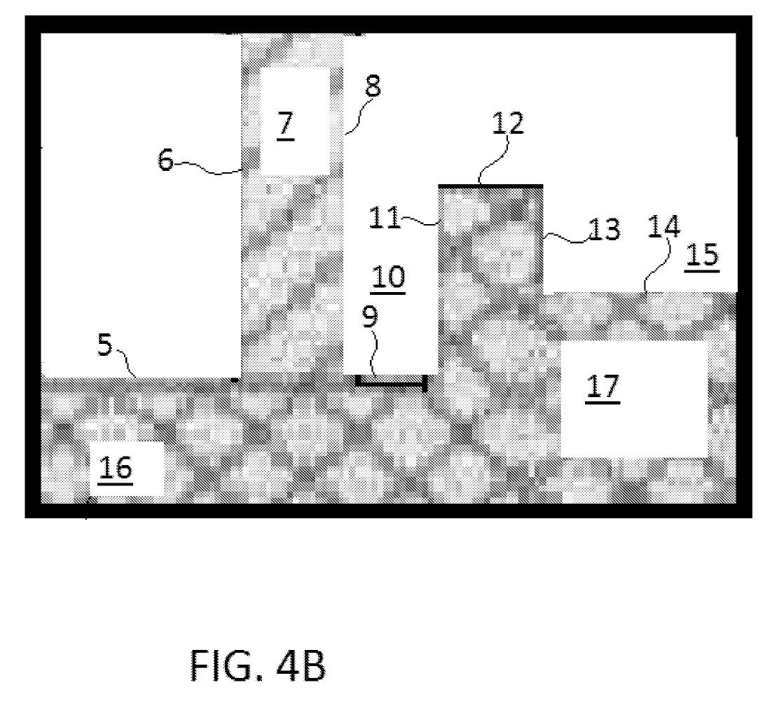

FIG. 4A shows an area that is exploded in FIG. 4B

FIG. 4B presents details of one embodiment of the invention which include:

An upper planer support area 5 of the lower component 3 of the crucible assembly, an outer surface 6 and inner surface 8 of a vertical wall 7 of the upper component 1 of the crucible assembly, an inner surface area 9 of the upper planer support area 5 of the lower component 3 of the crucible assembly, a gap area 10, a first vertical wall 11, crown horizontal surface 12 and second vertical wall 13 and raised horizontal planer surface 14 of the lower component 3. A void area defined by the second vertical wall 13 and the raised horizontal planer surface 14 and inner base area of the lower component 3.

Disclosed embodiments include:

1. A method of vaporizing lens coating material with a crucible assembly and dual beams of electrons, the method comprising the steps of:

a) applying dual beams 4 of electrons to a upper component 1 and a lower component 3 of a crucible assembly, the crucible assembly containing lens coating material 2;

b) using a crucible assembly comprising a lower component and an upper component with the upper component comprising a vertical wall 7 having an inner surface 8 and outer surface 6 and a horizontal surface, with the vertical wall circular in shape and the vertical wall resting upon an upper planer support area 5 of the lower component 3;

c) the crucible assembly comprising a lower component 3, the lower component comprising an upper planer support area 5 supporting the vertical wall 7 of the upper component 1, an inner surface area 9 attached to the upper planer support area 5, the inner surface area attached to a first vertical wall 11, a crown horizontal surface 12 attached to the first vertical wall 11 and a second vertical wall 13 and a raised horizontal planer surface 15 attached to the second vertical wall 13; and

2. The method above wherein an air gap 10 is found between the inner surface of the vertical wall 8 of the upper component 1 and the inner surface area 9 and first vertical wall 11 of the lower component 3.

3. The method of 1 above using a lower component comprising an outer base area 16 and an inner base area 17.

4. The method of 3 above wherein the inner base area 17 is raised higher than the outer base area 16.

5. A system for vaporizing lens coating material held within a crucible assembly by use of dual beams of electrons, the system comprising:

a) dual beams 4 of electrons applied to a upper component 1 and a lower component 3 of a crucible assembly, the crucible assembly containing lens coating material 2;

b) a crucible assembly comprising a lower component and an upper component with the upper component comprising a vertical wall 7 having an inner surface 8 and outer surface 6 and a horizontal surface, with the vertical wall circular in shape and the vertical wall resting upon an upper planer support area 5 of the lower component 3;

c) the crucible assembly comprising a lower component 3, the lower component comprising an upper planer support area 5 supporting the vertical wall 7 of the upper component 1, an inner surface area 9 attached to the upper planer support area 5, the inner surface area attached to a first vertical wall 11, a crown horizontal surface 12 attached to the first vertical wall 11 and a second vertical wall 13 and a raised horizontal planer surface 15 attached to the second vertical wall 13; and

6. The system of 5 above wherein an air gap 10 is found between the inner surface of the vertical wall 8 of the upper component 1 and the inner surface area 9 and first vertical wall 11 of the lower component 3.

7. The system of 5 above with a lower component comprising an outer base area 16 and an inner base area 17.

8. The system of 7 above wherein the inner base area 17 is raised higher than the outer base area 16.

What is claimed is:

1. A method of vaporizing lens coating material with a crucible assembly and dual beams of electrons, the method comprising the steps of:
a) applying dual beams of electrons to a upper component and a lower component of a crucible assembly, the crucible assembly containing lens coating material;
b) using a crucible assembly comprising a lower component and an upper component with the upper component comprising a vertical wall having an inner surface and outer surface and a horizontal surface, with the vertical wall circular in shape and the vertical wall resting upon an upper planer support area of the lower component; and
c) the crucible assembly comprising a lower component, the lower component comprising an upper planer support area supporting the vertical wall of the upper component, an inner surface area attached to the upper planer support area, the inner surface area attached to a first vertical wall, a crown horizontal surface attached to the first vertical wall and a second vertical wall and a raised horizontal planer surface attached to the second vertical wall.

2. The method of claim 1 wherein an air gap is found between the inner surface of the vertical wall of the upper component and the inner surface area and first vertical wall of the lower component.

3. The method of claim 2 using a lower component comprising an outer base area and an inner base area.

4. The method of claim 3 wherein the inner base area is raised higher than the outer base area.

5. A system for vaporizing lens coating material held within a crucible assembly by use of dual beams of electrons, the system comprising:
a) dual beams of electrons applied to a upper component and a lower component of a crucible assembly, the crucible assembly containing lens coating material;
b) a crucible assembly comprising a lower component and an upper component with the upper component comprising a vertical wall having an inner surface and outer surface and a horizontal surface, with the vertical wall circular in shape and the vertical wall resting upon an upper planer support area of the lower component;
c) the crucible assembly comprising a lower component, the lower component comprising an upper planer support area supporting the vertical wall of the upper component, an inner surface area attached to the upper planer support area, the inner surface area attached to a first vertical wall, a crown horizontal surface attached to the first vertical wall and a second vertical wall and a raised horizontal planer surface attached to the second vertical wall; and

6. The system of claim 5 wherein an air gap is found between the inner surface of the vertical wall of the upper component and the inner surface area and first vertical wall of the lower component.

7. The system of claim 5 with a lower component comprising an outer base area and an inner base area.

8. The system of claim 7 wherein the inner base area is raised higher than the outer base area.
